(19) United States
(12) Patent Application Publication
(10) Pub. No.: US 2018/0158686 A1
(43) Pub. Date: Jun. 7, 2018

(54) Deposition Of Metal Films

(71) Applicant: Applied Materials, Inc., Santa Clara, CA (US)

(72) Inventors: Avgerinos V. Gelatos, Scotts Valley, CA (US); Takashi Kuratomi, San Jose, CA (US); Hyuck Lim, Sunnyvale, CA (US); I-Cheng Chen, San Jose, CA (US); Mei Chang, Saratoga, CA (US)

(21) Appl. No.: 15/815,932

(22) Filed: Nov. 17, 2017

Related U.S. Application Data
(60) Provisional application No. 62/426,002, filed on Nov. 23, 2016.

(51) Int. Cl. H01L 21/285; H01L 21/768; C23C 16/50; C23C 16/08

(52) U.S. Cl. CPC H01L 21/28518; H01L 21/76879; H01L 21/02068; C23C 16/50; C23C 16/08; H01L 21/76889

(57) ABSTRACT

Methods to selectively deposit titanium-containing films on silicon-containing surfaces in high aspect ratio features of substrates comprise plasma-enhanced chemical vapor deposition (PECVD) process at a plasma powers in the range of about 1 to less than about 700 mWatts/cm² and frequencies in the range of about 10 kHz to about 50 MHz. The titanium films may be selectively deposited with a selectivity in the range of at least about 1.3:1 metallic silicon surfaces relative to silicon dioxide surfaces.

### CROSS-REFERENCE TO RELATED APPLICATIONS

This application claims priority to U.S. Provisional Application No. 62/426,002, filed Nov. 23, 2016, the entire disclosure of which is hereby incorporated by reference herein.

### FIELD

Embodiments of the disclosure generally relate to methods of depositing a metal film on metallic surfaces. More particularly, embodiments of the disclosure are directed to methods of improving bottom film coverage, and further depositing a metal film on a metallic surface selectively over a surface of a different material such as a metal oxide, a metal nitride, or a metal-oxide-nitride.

### BACKGROUND

Integrated circuits are made possible by processes that produce intricately patterned material layers on substrate surfaces. Producing patterned material on a substrate requires controlled methods for deposition of desired materials. Selectively depositing a film on one surface relative to a different surface is useful for patterning and other applications.

High aspect ratio apertures including contacts, vias, lines, and other features used to form multilevel interconnects, which use cobalt, tungsten, or copper for example, continue to decrease in size as manufacturers strive to increase circuit density and quality. Titanium is well known to adapt as a silicide material. The selective titanium deposition is an ongoing goal to improve Rc (contact resistance) performance.

Plasma-Enhanced Chemical Vapor Deposition (PECVD) to form titanium with TiCl₄ as the precursor is widely used in the semiconductor industry but conventional TiCl₄ conditions, for example 600° C.-700° C. show poor bottom coverage of high aspect ratio apertures, which are decreasing in size.

There is a continuing need to provide silicide layer in desired locations, including bottom coverage and selective deposition of titanium films.

### SUMMARY

One or more embodiments of the disclosure are directed to processing methods comprising depositing a metal film on a first surface of a substrate selectively over a second surface that is a different material from the first surface of the substrate within a processing chamber during a plasma-enhanced chemical vapor deposition (PECVD) process.

Additional embodiments of the disclosure are directed to processing methods comprising positioning a substrate surface within a processing chamber. The substrate surface has at least one feature thereon, the at least one feature creating a gap with a bottom, a top, and sidewalls, the bottom comprising a metallic element or alloy, either of which optionally being doped, and the sidewalls comprising a metal oxide, a metal nitride, or a metal-oxide-nitride, each of which optionally being carbon-doped. The substrate surface is exposed to a metal halide precursor gas and a hydrogen-containing reducing co-reactant precursor during plasma-enhanced chemical vapor deposition (PECVD) process at a substrate temperature in the range of about 300° C. to less than 500° C. and a plasma power in the range of about 1 to less than about 700 mWatts/cm² to form a metal film on the bottom over the sidewalls of the feature.

Further embodiments of the disclosure are directed to processing methods comprising positioning a substrate with a first surface of: metallic silicon (Si), metallic germanium (Ge), or SiGe alloy, each of which optionally being doped with phosphorus (P), arsenic (As), and/or boron (B), and a second surface of a metal oxide, a metal nitride, or a metal-oxide-nitride, each of which optionally being carbon-doped in a processing chamber. A metal precursor comprising a titanium halide; a zirconium halide, and/or a hafnium halide; hydrogen; and a carrier gas flow into the processing chamber. The metal precursor and the hydrogen are energized upon application of a plasma power in the range of about 1 to less than about 700 mWatts/cm² and a frequency in the range of about 10 kHz to about 50 MHz. The energized metal precursor and hydrogen are reacted to deposit a metal film selectively on the first surface relative to the second surface with a selectivity of at least about 10:1.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a process flow diagram of a process in accordance with one or more embodiments of the disclosure;

FIG. 2 is a partial cross-sectional view of a substrate with a feature;

FIG. 3 is a partial cross-sectional view of a selectively deposited titanium film in a feature;

FIG. 4 is a graph of normalized titanium film thickness versus deposition time (seconds); and

FIGS. 5-7 provide Transmission Electron Microscope (TEM) images of a high aspect ratio structure after formation of titanium film.

### DETAILED DESCRIPTION

Embodiments of the disclosure provide methods to deposit titanium films on silicon-containing surfaces. Ti-silicide is used as silicide formation layer in high aspect ratio apertures for contact application. As node sizes are reduced to less than 20 nm and metal gate is adapted, thermal budget of substrate processing temperatures decrease (<500° C.). The disclosure advantageously improves Ti bottom coverage of narrow trenches and deposition selectivity on Si (active junction) and SiO₂ (sidewall and field) to reduce contact resistance at less than 500° C. deposition temperature. Bottom coverage improvement and selective deposition between Si and SiO₂ with PECVD Ti allows for wider room for post-metal fill process as well as improved device performance.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used. In one or more embodiments, the first substrate surface will comprise a metal, and the second substrate surface will comprise a dielectric, or vice versa. In some embodiments, a substrate surface may comprise certain functionality (e.g., —OH, —NH, etc.).

As used in this specification and the appended claims, the terms “reactive gas”, “precursor”, “reactant”, and the like, are used interchangeably to mean a gas that includes a species which is reactive with a substrate surface.

Chemical Vapor Deposition (CVD) processes, including plasma-enhanced chemical vapor deposition (PECVD), are different from Atomic Layer Deposition (ALD). An ALD process is a self-limiting process where a single layer of material is deposited using a binary (or higher order) reaction. The process continues until all available active sites on the substrate surface have been reacted. A CVD process is not self-limiting, and a film can be grown to any predetermined thickness. PECVD relies on use of energy in a plasma state to create more reactive radicals.

Embodiments of the disclosure provide processing methods to provide titanium layers in desired locations, including improved bottom coverage and selective deposition of titanium films in high aspect ratio features. As used in this specification and the appended claims, the terms “selective deposition of” and “selectively forming” a film on one surface over another surface, and the like, means that a first amount of the film is deposited on the first surface and a second amount of film is deposited on the second surface, where the second amount of film is less than the first amount of film or none. The term “over” used in this regard does not imply a physical orientation of one surface on top of another surface, rather a relationship of the thermodynamic or kinetic properties of the chemical reaction with one surface relative to the other surface. For example, selectively depositing a titanium film onto a silicon (Si) surface over a silicon dioxide (SiO₂) surface means that the titanium film deposits on the Si surface and less titanium film deposits on the SiO₂ surface; or that the formation of the titanium film on the Si surface is thermodynamically or kinetically favorable relative to the formation of a titanium film on the SiO₂ surface. Stated differently, the film can be selectively deposited onto a first surface relative to a second surface means that deposition on the first surface is favorable relative to the deposition on the second surface.

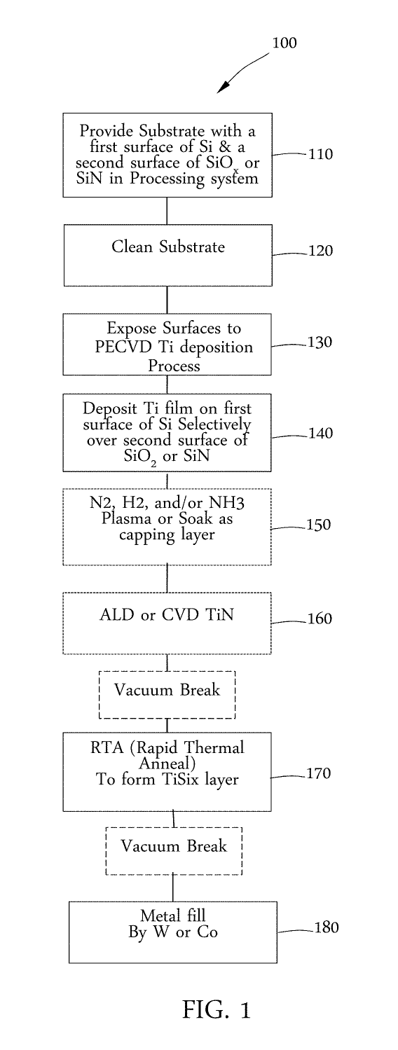

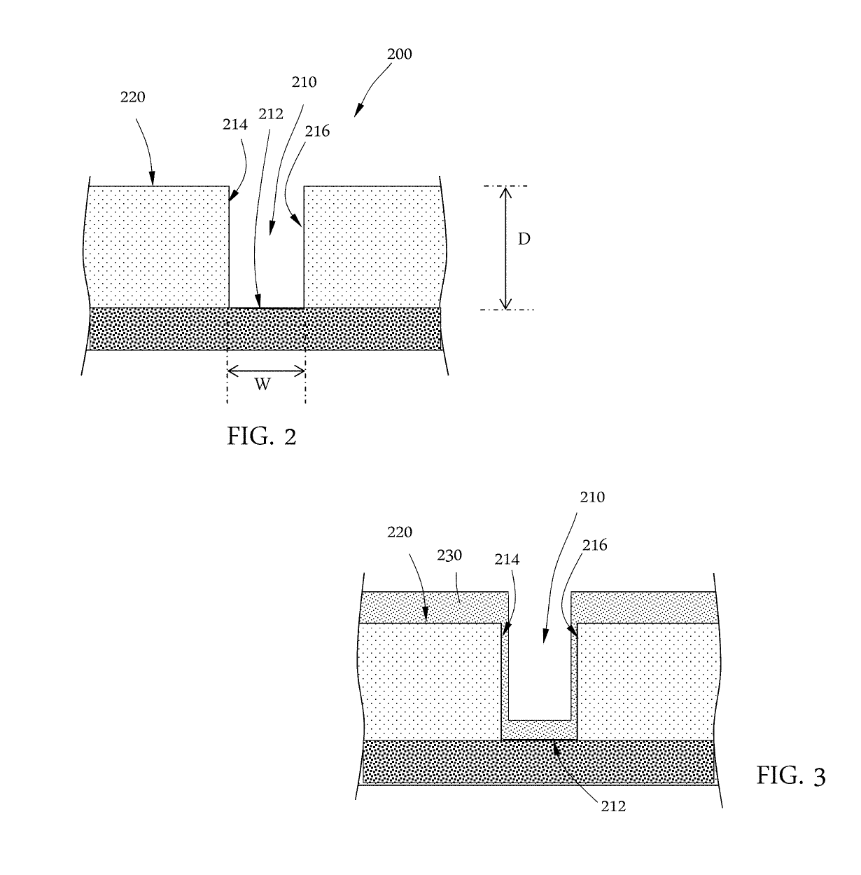

Embodiments of the disclosure are directed to methods of depositing a metal film on metallic surfaces preferentially over surfaces of a different material using PECVD. FIG. 1 shows a process flow diagram of a process 100 in accordance with one or more embodiments of the disclosure. For the purposes of FIG. 1, the metal film comprises titanium, the metallic surface comprises Si, and the different material comprises SiOx or SiN. The present disclosure is directed to metal films that may comprise, but are not limited to, titanium, zirconium, and/or hafnium. These metal films may optionally be doped by a dopant including but not limited to phosphorus (P), arsenic (As), and/or boron (B). Metallic surfaces may comprise, but are not limited to, Si, Ge, and/or SiGe. Surfaces of a different material may comprise, but are not limited to silicon oxide (SiOₓ), silicon nitride (SiN), silicon oxide-nitride (SiON), each of which optionally being carbon-doped. FIG. 2 is a partial cross-sectional view of a substrate with a feature and FIG. 3 is a partial cross-sectional view of a selectively deposited titanium film in a feature. With reference to FIGS. 1-3, a substrate 200 comprising a feature 210 having a bottom surface 212 and sidewalls 214, 216 is provided for processing at 110. In this embodiment, the bottom surface comprises Si and the sidewalls comprise SiOx or SiN. As used in this regard, the term “provided” means that the substrate is placed into a position or environment for further processing. Some figures show substrates having a single feature for illustrative purposes; however, those skilled in the art will understand that there can be more than one feature. The shape or profile of the feature 210 can be any suitable shape or profile including, but not limited to, (a) vertical sidewalls and bottom surface, (b) tapered sidewalls, (c) under-cutting, (d) reentrant profile, (e) bowing, (f) micro-trenching, (g) curved bottom surface, and (h) notching. As used in this regard, the term “feature” means any intentional surface irregularity. Suitable examples of features include, but are not limited to trenches and holes which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

At 120 in a first chamber, the substrate 200 is cleaned to remove native oxide, leaving a clean substrate surface. The native oxide can be removed by any suitable technique including, but not limited to, a dry etch process known as a SiConi™ etch. A SiConi™ etch is a remote plasma assisted dry etch process which involves the simultaneous exposure of a substrate to H₂, NF₃ and NH₃ plasma by-products. Remote plasma excitation of the hydrogen and fluorine species allows plasma-damage-free substrate processing. The SiConi™ etch is largely conformal and selective towards silicon oxide layers but does not readily etch silicon regardless of whether the silicon is amorphous, crystalline or polycrystalline.

The substrate 200 has a (clean) substrate surface 220. The at least one feature 210 forms an opening in the substrate surface 220. The feature 210 extends from the substrate surface 220 to a depth D to the bottom surface 212, which comprises silicon (Si). The feature 210 has a first sidewall 214 and a second sidewall 216 that define a width W of the feature 210. The sidewalls comprise a silicon oxide (SiOx), for example, silicon dioxide (SiO₂) or silicon nitride (SiN). The open area formed by the sidewalls and bottom are also referred to as a gap.

At 130 of FIG. 1 in a second chamber, the Si and SiOₓ/SiN surfaces are exposed to a PECVD deposition process using titanium and reductant precursors and optionally a carrier gas. At 140 of FIG. 1, a titanium film 230 is deposited on the Si surface selectively over the SiOₓ/SiN surfaces. At 150 of FIG. 1, there is an optional N₂, H₂, and/or NH₃ plasma treatment or soak. In an embodiment, formation of the titanium film 230 comprises exposing the substrate surface to a titanium precursor and a reactant under plasma-generating conditions. For use of titanium chloride and hydrogen, without being bound by any particular theory of operation, it is believed that the titanium chloride reacts with H+/H* species to deposit a titanium film on the substrate. The titanium film forms on the Si and SiOₓ/SiN surfaces of the feature. Unreacted titanium chloride is believed to etch the titanium film formed on the SiOₓ/SiN surface(s) to selectively deposit a titanium film on the Si surface. The titanium film can form equally or unequally on the Si and SiOₓ/SiN surfaces with etching resulting in selective deposition. In some embodiments, the titanium film is formed on the Si surface preferentially to the SiOₓ/SiN surface and etching increases the selectivity.

The selectivity of the deposition is at least about 1.3:1. The selectivity may be in the range of about 1.3:1 to at least about 100:1. In some embodiments, the selectivity is greater than or equal to about 1.5:1, 2:1, 5:1, 8:1, 10:1, 15:1, 20:1, 25:1, 50:1 or more.

According to one or more embodiments, the metal film has a thickness in the range of about 10 Å to about 100 Å on the bottom metallic/alloy surface and 10 Å to ˜0 Å on the sidewall surfaces (metal oxides, metal nitrides, metal-oxide-nitrides).

The processing chamber may be any chamber suitable for PECVD. Fluid precursors are supplied to the processing chamber, which are then excited with a plasma power in a region of the chamber. There is an electric power supply electrically coupled to the processing chamber, which may be configured to deliver an adjustable amount of power to the chamber depending on the process.

The metal precursor may comprise a metal halide. The halide can be any suitable halogen. The metal halide can be a mixture of different halogens or substantially the same halogen atom. In some embodiments, the metal halide comprises substantially only chlorine atoms. As used in this regard, “substantially only” means that there is greater than or equal to about 95 atomic percent of the stated halogen species. In some embodiments, the halogen is one or more of fluorine, chlorine, bromine or iodine. In some embodiments, there are substantially no fluorine atoms; meaning that there is less than about 1% on an atomic basis of all halogen atoms.

In one or more embodiments, the metal halide is a metal chloride. The metal chlorides can be a mixture of titanium oxidation states or substantially all the same oxidation state (i.e., >95% the same oxidation state on an atomic basis). For example, the titanium chloride TiClₓ can be a mixture of titanium oxidation states or substantially all the same oxidation state (i.e., >95% the same oxidation state on an atomic basis). For example, the titanium chloride can be a mixture of TiCl₃ and TiCl₄ species, or other species. Other metal chlorides include zirconium chloride and hafnium chloride.

The reductant comprises a reducing co-reactant which may be a hydrogen-containing precursor. The hydrogen-containing precursor may comprise at least one precursor selected from H₂, NH₃, hydrocarbons, or the like. In some embodiments, the first precursor comprises hydrogen (H₂) and energizing the first precursor produces H⁺ and H* species. In some embodiments, the hydrogen ions and radicals are formed as part of a plasma.

The metal film deposited may comprise or consist essentially of the metal, for example titanium, zirconium, or hafnium. As used in this regard, the term “consists essentially of” means that the film is greater than or equal to about 95 atomic percent of the specified component. In some embodiments, the metal film is greater than about 96, 97, 98 or 99 atomic percent of the specified component.

For formation of the metal film, the metal precursor and the reductant may be co-flowed or alternately pulsed into the PECVD processing chamber optionally along with a carrier gas to form a direct plasma. An exemplary carrier gas is Ar. The substrate may be heated to a temperature within a range from about 50° C. to about 500° C., preferably, from about 100° C. to less than 500° C., from about 300° C. to less than 500° C., and more preferably, from about 300° C. to about 440° C.

A plasma power may be in the range of about 1 to less than about 700 mWatts/cm², or about 70 to less than about 350 mWatts/cm², or even about 90 mWatts/cm² and all values and subranges therein. Frequency may be in the range of about 10 kHz to about 50 MHz, or 350 kHz to 40 MHz, or even about 13.56 MHz and all values and subranges therein. Duty cycle may be in the range of 1 to 90% and all values and subranges therein. The plasma power may be pulsed, providing power every about 0.00001 to about 100 seconds for a duration of about 0.0000001 to about 90 seconds and all values and subranges therein.

When a carrier gas is used, for example, argon, the flow rate may be in the range of 3 to 400 sccm and all values and subranges therein.

According to one or more embodiments, the substrate is subjected to processing prior to and/or after forming the metal layer. For example, in one or more embodiments, after formation of the metal, e.g., titanium, layer, optionally at 160 of FIG. 1, titanium nitride is deposited as barrier layer. After a vacuum break, at 170 optional RTA (Rapid Thermal Anneal) is implemented to form titanium silicide layer. After a vacuum break, at 180 the depth and width of the remaining portion of the feature is filled with tungsten or cobalt to form an interconnect. The titanium and titanium nitride processing can be performed in the same chamber or in one or more separate processing chambers. Or nitridation on deposited Ti film also can be worked which is processed by N₂, H₂, and/or NH₃ with applying RF plasma or soak.

In some embodiments, the substrate is moved from a first chamber to a separate, next chamber for further processing. The substrate can be moved directly from the first chamber to the separate processing chamber, or the substrate can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

### EXAMPLES

### Example 1

### Comparative

A titanium film was formed in a feature of a substrate surface where a bottom of the feature and sidewall of the feature were silicon dioxide (SiO₂). The substrate temperature was ˜440° C. and pressure was 5 Torr. Titanium chloride (TiCl₄), hydrogen (H₂), and argon (Ar) were supplied to a PECVD chamber. After deposition for ˜300 seconds, the chamber was purged and pumped. The following Table 1 provides conditions and resulting titanium film formation.

TABLE 1

| | | | Normalized | Normalized |
|---|---|---|---|---|
| | RF power at | Carrier Ar | Bottom film | Sidewall film |
| | 350 kHz | flow | thickness & | thickness & |
| Example | [mW/cm²] | [sccm] | %^{(A)} | %^{(B)} |
| 1-A | 700 | 30 | 4.9 | 2.1 |
| Comparative | | | 67% | 30% |

^{(A)}% bottom thickness is thickness of bottom film divided by thickness of film formed on substrate surface (not in feature).
^{(B)}% sidewall thickness is thickness of sidewall film divided by thickness of film formed on substrate surface (not in feature).

### Example 2

Effect of Power and Carrier Gas Flow.

A titanium film was formed in a feature of a substrate surface, where a bottom of the feature and sidewall of the feature were silicon dioxide (SiO₂). The substrate temperature was ˜440° C. and pressure was 5 Torr. Titanium chloride (TiCl₄), hydrogen (H₂), and argon (Ar) were supplied to a PECVD chamber. After deposition for ˜600 seconds, the chamber was purged and pumped. The following Table 2 provides conditions and resulting titanium film formation.

TABLE 2

| | | | Normalized | Normalized | |
|---|---|---|---|---|---|
| | RF power at | Carrier Ar | Bottom film | Sidewall film | |
| | 350 kHz | flow | thickness & | thickness & | Selectivity |
| Example | [mW/cm²] | [sccm] | %^{(A)} | %^{(B)} | (Bottom:Sidewall) |
| 2-A | 90 | 30 | 3.5 | 1.0 | 3.5 |
| | | | 79% | 23% | |
| 2-B | 90 | 125 | 3.4 | 1.2 | 2.8 |
| | | | 100% | 35% | |

^{(A)}% bottom thickness is thickness of bottom film divided by thickness of film formed on substrate surface (not in feature).
^{(B)}% sidewall thickness is thickness of sidewall film divided by thickness of film formed on substrate surface (not in feature).

Lowering RF power improved bottom coverage and selectivity when comparing 2-A to 1-A. Lower RF power facilitates reducing Ti₊ to improve bottom coverage and reduce overhang and minimizes H₊/H* kinetic energy to reduce oxygen reduction from SiO₂. Increasing carrier gas flow with respect to 2-B compared to 2-A resulted in 100% bottom coverage and comparable selectivity. An increase in carrier gas increases TiCl₄ which etches unreacted Ti on SiO₂ in simultaneous deposition and etch process.

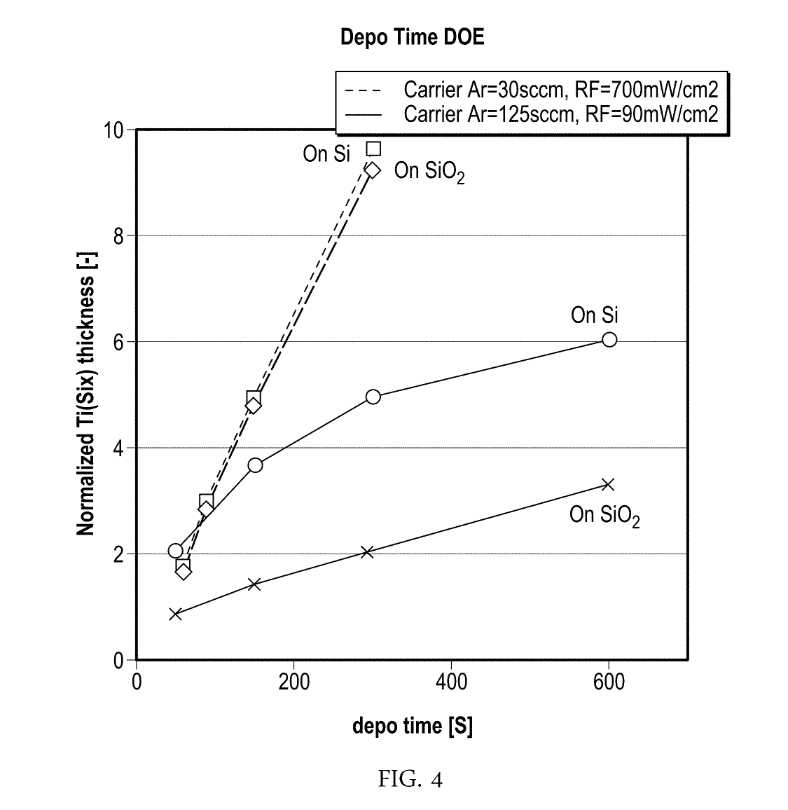

FIG. 4 provides a graph of normalized titanium film thickness versus deposition time (seconds) for Example 1-A (comparative) solid line of graph and Example 2-B dotted line of graph. The higher carrier gas rate and lower power resulted in faster deposition on Si than that on SiO₂ which can improve selectivity.

### Example 3

Effect of Pressure.

A titanium film was formed in a feature of a substrate surface, where a bottom of the feature was silicon (Si) and sidewalls of the feature was silicon dioxide (SiO₂). The substrate temperature was ˜440° C. and pressure was varied. Titanium chloride (TiCl₄), hydrogen (H₂), and argon (Ar) were supplied to a PECVD chamber. After deposition for ˜300 seconds for 3-A and ˜600 seconds for 3-B and 3-C, the chamber was purged and pumped. The following Table 3 provides conditions and resulting titanium formation at field on SiN, and sidewalls on SiO₂ and titanium silicide formation at bottom on Si.

TABLE 3

| | | | | Normalized | Normalized | |
|---|---|---|---|---|---|---|
| | | RF power at | Carrier Ar | Bottom film | Sidewall | Selectivity |
| | Pressure | 350 kHz | flow | thickness | film | (Bottom: |
| Example | [Torr] | [mW/cm²] | [sccm] | & %^{(A)} | thickness | Sidewall) |
| 3-A | 5 | 700 | 25 | 9.6 | 7.6 | 1.3:1 |
| | | | | 50% | | |
| 3-B | 5 | 90 | 125 | 5.6 | 1.4 | 4:1 |
| | | | | 160% | | |
| 3-C | 25 | 90 | 125 | 5.3 | <0.5 | >10:1 |
| | | | | 220% | | |

^{(A)}% bottom thickness is thickness of bottom film divided by thickness of film formed on substrate surface (not in feature).

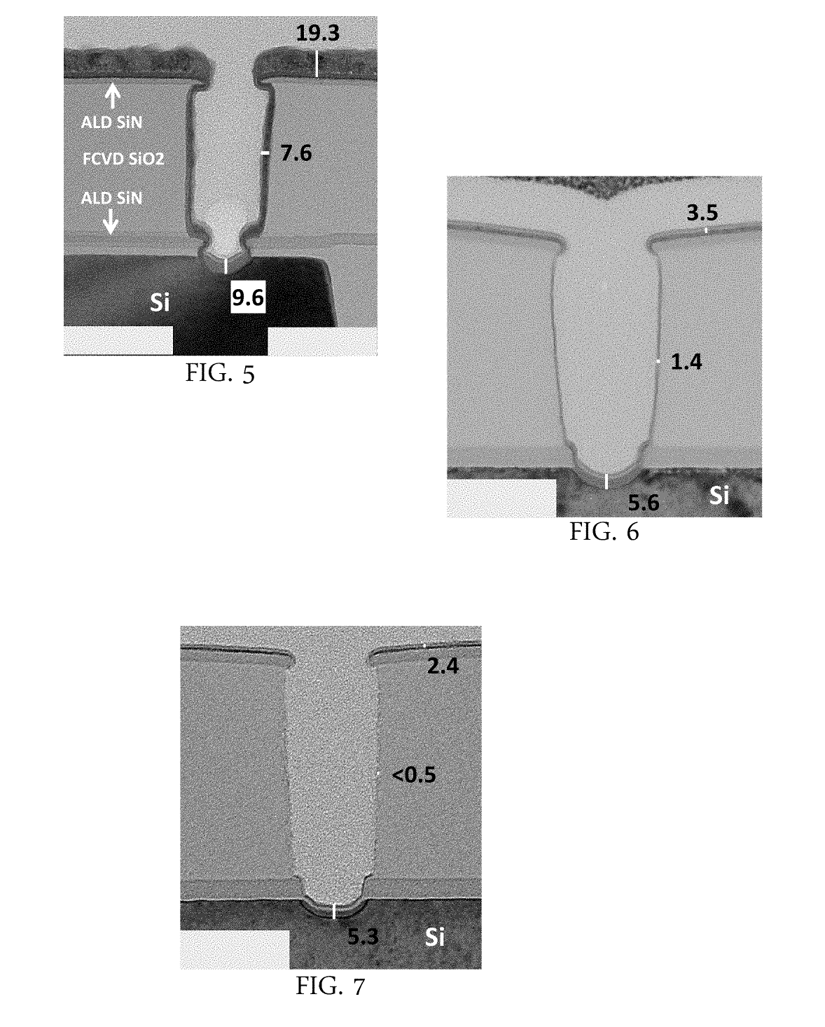

Higher pressure reduced kinetic energy of Ti₊ and H+. Achieved >200% bottom coverage and >10:1 selectivity. FIGS. 5-7 show TEM images of a high aspect ratio structure after formation of TiSix film for Examples 3-A to 3-C, respectively.

### Example 4

Pulsed RF.

A titanium film was formed in a feature of a substrate surface, where a bottom of the feature was silicon (Si) and sidewalls of the feature was silicon dioxide (SiO₂). The substrate temperature was ˜440° C., RF power at 350 kHz was 65 W (90 mW/cm²), carrier flow rate was 125 sccm, and pressure was 5 Torr. Titanium chloride (TiCl₄), hydrogen (H₂), and argon (Ar) were supplied to a PECVD chamber. After deposition, the chamber was purged and pumped. The following Table 4 provides conditions and resulting titanium film formation.

TABLE 4

| | | Normalized | Normalized | |
|---|---|---|---|---|
| | | Bottom film | Sidewall | |
| | | thickness & | film | Selectivity |
| Example | Deposition | %^{(A)} | thickness | (Bottom:Sidewall) |
| 3-B | 600 | 5.6 | 1.4 | 4:1 |
| | seconds | 160% | | |
| | continuous | | | |
| 4-A | 0.8 | 6.0 | 1.1 | 6:1 |
| | seconds | 200% | | |
| | on/1.1 | | | |
| | second off | | | |
| | 790 cycles | | | |

^{(A)}% bottom thickness is thickness of bottom film divided by thickness of film formed on substrate surface (not in feature).

Pulsed RF improves selectivity and bottom coverage.

### Example 5

High RF Frequency.

A titanium film was formed in a feature of a substrate surface, where a bottom of the feature was silicon (Si) and sidewalls of the feature was silicon dioxide (SiO₂). The substrate temperature was ˜440° C., carrier flow rate was 125 sccm, and pressure was 5 Torr. Titanium chloride (TiCl₄), hydrogen (H₂), and argon (Ar) were supplied to a PECVD chamber. After deposition for ˜600 seconds, the chamber was purged and pumped. The following Table 5 provides conditions and resulting titanium film formation, where N/U refers to non-uniformity.

TABLE 5

| | | | Bottom film | | |
|---|---|---|---|---|---|
| | | Normalized | Sheet | | |
| | | Bottom film | Resistance | Bottom film | Selectivity |
| Example | RF Frequency | thickness | Rs | Resistivity | (Bottom:Sidewall) |
| 5-A | 350 kHz | 6.55 | 374.7 Ohm/sq | 245.5 | 2.4:1 |
| | 90 mW/cm² | N/U 3.2%1 s | N/U 1.4%1 s | uOhm-cm | Center |
| | 600 sec | | | | 1.7:1 Avg |
| 5-B | 13.56 MHz | 6.93 | 364.5 Ohm/sq | 252.6 | 5.1:1 |
| | 140 mW/cm² | N/U 6.3%1 s | N/U 1.9%1 s | uOhm-cm | Center |
| | 600 sec | | | | 3.3:1 Avg |

13.56 MHz improves selectivity with similar resistivity on Si.

### Example 6

Effect of Duty Cycle.

A titanium film was formed in a feature of a substrate surface, where a bottom of the feature was silicon (Si) and sidewalls of the feature was silicon oxide (SiOₓ) or silicon nitride (SiN). The substrate temperature was ˜450° C., RF power at 13.56 MHz was 65 W (90 mW/cm²), pressure was 5 Torr. Titanium chloride (TiCl₄) 5 sccm, hydrogen (H₂) 6000 sccm, and argon (Ar) 18000 sccm were supplied to a PECVD chamber. After deposition, the chamber was purged and pumped. The following Table 6 provides conditions, resulting thickness of titanium film on the various surfaces, and selectivity.

TABLE 6

| | | Normalized | Normalized | Normalized | | |
|---|---|---|---|---|---|---|
| | | film | film | film | | |
| | | thickness | thickness | thickness | Selectivity | Selectivity |
| Example | Deposition | on SI | on SiOx | on CVD SiN | (Si:SiOx) | (Si:SiN) |
| 6-A | Continuous | 7.380 | 0.727 | 2.665 | 10.2 | 2.8 |
| Comparative | | | | | | |
| 6-B | 10% Duty | 4.221 | 0.223 | 0.193 | 18.9 | 21.8 |
| | Cycle | | | | | |
| 6-C | 15% Duty | 5.635 | 0.428 | 0.510 | 13.2 | 11.0 |
| | Cycle | | | | | |
| 6-D | 25% Duty | 6.452 | 0.638 | 1.528 | 10.1 | 4.2 |
| | Cycle | | | | | |
| 6-E | 50% Duty | 6.743 | 0.722 | 1.981 | 9.3 | 3.4 |
| | Cycle | | | | | |
| 6-F | 75% Duty | 6.960 | 0.616 | 2.293 | 11.3 | 3.0 |
| | Cycle | | | | | |

Selectivity on CVD SiN improves from about 3 to up about 21:1 with low duty cycle. It is noted that deposition rates also decreased. Selectivity on Ox improves from about 10 to up about 19 with low duty cycle.

### Example 7

Effect of Power at Low Duty Cycle.

A titanium film was formed on an unpatterned substrate surface. The substrate temperature was ˜450° C., RF power at 13.56 MHz was varied at 10% duty cycle, pressure was 5 Torr. Titanium chloride (TiCl₄) 5 sccm, hydrogen (H₂) 6000 sccm, and argon (Ar) 18000 sccm were supplied to a PECVD chamber. After deposition, the chamber was purged and pumped. The following Table 7 provides conditions, deposition time, and resulting selectivity.

TABLE 7

| | | Normalized | | |
|---|---|---|---|---|
| | | film | | |
| | | thickness | Normalized film | Selectivity |
| Example | RF Frequency | on Si | thickness on SiN | (Si:SiN) |
| 7-A | 13.56 MHz | 4.221 | 0.193 | 21.9 |
| | 100 W | | | |
| | 142 mW/cm² | | | |
| | 400 sec | | | |
| 7-B | 13.56 MHz | 6.077 | 0.254 | 23.9 |
| | 100 W | | | |
| | 142 mW/cm² | | | |
| | 900 sec | | | |
| 7-C | 13.56 MHz | 8.464 | 0.387 | 21.9 |
| | 100 W | | | |
| | 142 mW/cm² | | | |
| | 1800 sec | | | |
| 7-D | 13.56 MHz | 5.941 | 1.496 | 4.0 |
| | 200 W | | | |
| | 283 mW/cm² | | | |
| | 400 sec | | | |
| 7-E | 13.56 MHz | 7.203 | 1.844 | 3.9 |
| | 200 W | | | |
| | 283 mW/cm² | | | |
| | 900 sec | | | |
| 7-F | 13.56 MHz | 4.145 | 1.636 | 2.5 |
| | 400 W | | | |
| | 566 mW/cm² | | | |
| | 100 sec | | | |
| 7-G | 13.56 MHz | 5.577 | 2.442 | 2.3 |
| | 400 W | | | |
| | 566 mW/cm² | | | |
| | 400 sec | | | |

Higher power increased TiSiN formation on SiN substrate even at low duty cycle.

### Example 8

Effect of Generator Pulsing Frequency and Duty Cycle.

A titanium film was formed in a feature of a substrate surface, where a bottom of the feature was silicon (Si) and sidewalls of the feature was silicon oxide (SiOx) or silicon nitride (SiN). RF power was 65 W (92 mW/cm²). Duty cycle # reflects how long the power is on and how long the power is off. The pulsing was done at two different frequencies: 10 kHz and 5 kHz. The substrate temperature was ˜450° C., pulsing frequency and duty cycle were varied, pressure was 5 Torr. Titanium chloride (TiCl₄) 5 sccm, hydrogen (H₂) 6000 sccm, and argon (Ar) 18000 sccm were supplied to a PECVD chamber. After deposition, the chamber was purged and pumped. The following Table 8 provides conditions, resulting thickness of titanium film on the various surfaces, and selectivity.

TABLE 8

| | | Normalized | Normalized | Normalized | | |
|---|---|---|---|---|---|---|
| | | film | film | film | | |
| | | thickness | thickness | thickness | Selectivity | Selectivity |
| Example | Conditions | on Si | on SiOx | on SiN | (Si:SiOx) | (Si:SiN) |
| 8-A | Continuous | 6.650 | 1.094 | 2.930 | 6.1 | 2.3 |
| Comparative | | | | | | |
| 8-B | 10 kHz pulse | 6.616 | 0.704 | 2.202 | 9.4 | 3.0 |
| | 75% Duty | | | | | |
| | Cycle | | | | | |
| 8-C | 10 kHz pulse | 6.475 | 0.736 | 1.837 | 8.8 | 3.5 |
| | 50% Duty | | | | | |
| | Cycle | | | | | |
| 8-D | 10 kHz pulse | 5.867 | 0.516 | 1.064 | 11.4 | 5.5 |
| | 25% Duty | | | | | |
| | Cycle | | | | | |
| 8-E | 5 kHz | 7.088 | 0.790 | 2.214 | 9.0 | 3.2 |
| | 75% Duty | | | | | |
| | Cycle | | | | | |
| 8-F | 5 kHz | 6.281 | 0.707 | 1.784 | 8.9 | 3.5 |
| | 50% Duty | | | | | |
| | Cycle | | | | | |

Selectivity on CVD SiN improves from about 2.3 to up about 5.5:1 with low duty cycle. It is noted that deposition rates also decreased. Selectivity on Ox improves from about 6 to up about 11 with low duty cycle.

While the foregoing is directed to embodiments of the present disclosure, other and further embodiments of the disclosure may be devised without departing from the basic scope thereof, and the scope thereof is determined by the claims that follow.

What is claimed is:

1. A processing method comprising:
depositing a metal film on a first surface of a substrate selectively over a second surface that is a different material from the first surface of the substrate within a processing chamber during a plasma-enhanced chemical vapor deposition (PECVD) process.

2. The processing method of claim 1, wherein the first surface comprises a metallic element or alloy, either of which optionally being doped, and the second surface comprises a metal oxide, a metal nitride, or a metal-oxide-nitride, each of which optionally being carbon-doped.

3. The processing method of claim 2, wherein the first surface comprises metallic silicon (Si), metallic germanium (Ge), or SiGe alloy, each of which optionally being doped with phosphorus (P), arsenic (As), and/or boron (B), and the second surface comprises silicon oxide (SiOₓ), silicon nitride (SiN), silicon oxide-nitride (SiON), each of which optionally being carbon-doped.

4. The processing method of claim 1, wherein the metal film is selectively deposited with a selectivity of at least about 1.3:1 on the first surface relative to the second surface.

5. The processing method of claim 1, wherein the metal film comprises titanium (Ti), zirconium (Zr), or hafnium (Hf).

6. The processing method of claim 1, wherein the PECVD process comprises co-flowing a metal precursor and a reducing co-reactant precursor into the processing chamber.

7. The processing method of claim 6, wherein the metal precursor comprises a metal halide and the reducing co-reactant precursor comprises hydrogen.

8. The processing method of claim 1, wherein the PECVD process comprises a direct plasma at a plasma power in the range of about 1 to less than about 700 mWatts/cm² and a substrate temperature of ≤500° C.

9. The processing method of claim 1, wherein a plasma power is provided every about 0.00001 to about 100 seconds for a duration of about 0.0000001 to about 90 seconds.

10. The processing method of claim 1, wherein the PECVD process comprises a direct plasma at a frequency in the range of about 10 kHz to about 50 MHz.

11. A processing method comprising:
positioning a substrate surface within a processing chamber, the substrate surface having at least one feature thereon, the at least one feature creating a gap with a bottom, a top, and sidewalls, the bottom comprising a metallic element or alloy, either of which optionally being doped, and the sidewalls comprising a metal oxide, a metal nitride, or a metal-oxide-nitride, each of which optionally being carbon-doped; and
exposing the substrate surface to a metal halide precursor gas and a hydrogen-containing reducing co-reactant precursor during plasma-enhanced chemical vapor deposition (PECVD) process at a substrate temperature in the range of about 300° C. to less than 500° C. and a plasma power in the range of about 1 to less than about 700 mWatts/cm² to form a metal film selectively on the bottom over the sidewalls of the feature.

12. The processing method of claim 11, wherein the metal film is selectively deposited with a selectivity of at least about 10:1 on the bottom relative to the sidewalls.

13. The processing method of claim 11, wherein metal halide precursor gas comprises titanium chloride, zirconium chloride, or hafnium chloride, and the hydrogen-containing reducing co-reactant precursor comprises H₂.

14. The processing method of claim 11, wherein the bottom comprises metallic silicon (Si), metallic germanium (Ge), or SiGe alloy, each of which optionally being doped with phosphorus (P), arsenic (As), and/or boron (B), and the sidewalls comprise silicon oxide (SiOₓ), silicon nitride (SiN), silicon oxide-nitride (SiON), each of which optionally being carbon-doped.

15. A processing method comprising:
positioning a substrate with a first surface of: metallic silicon (Si), metallic germanium (Ge), or SiGe alloy, each of which optionally being doped with phosphorus (P), arsenic (As), and/or boron (B), and a second surface of a metal oxide, a metal nitride, or a metal-oxide-nitride, each of which optionally being carbon-doped in a processing chamber;
flowing a metal precursor comprising a titanium halide, a zirconium halide, and/or a hafnium halide; hydrogen; and a carrier gas into the processing chamber;
energizing the metal precursor and the hydrogen upon application of a plasma power in the range of about 1 to less than about 700 mWatts/cm² and a frequency in the range of about 10 kHz to about 50 MHz; and
reacting the energized metal precursor and hydrogen to deposit a metal film selectively on the first surface relative to the second surface with a selectivity of at least about 10:1.

16. The processing method of claim 15, wherein the frequency is about 13.56 MHz.

17. The processing method of claim 15, wherein a substrate temperature is ≤500° C.

18. The processing method of claim 17, wherein the substrate temperature is in the range of about 300° C. to about 440° C.

19. The processing method of claim 15 further comprising pulsing the plasma power.

20. The processing method of claim 19, wherein the plasma power is provided every about 0.00001 to about 100 seconds for a duration of about 0.0000001 to about 90 seconds.
